(19) United States
(12) Patent Application Publication
(10) Pub. No.: US 2010/0195571 A1
(43) Pub. Date: Aug. 5, 2010

(54) Wireless Communication Device and Retransmission Judging Method

(75) Inventors: Kenichi Kuri, Kanagawa (JP); Akihiko Nishio, Kanagawa (JP)

Correspondence Address: Dickinson Wright PLLC;James E. Ledbetter, Esq., International Square, 1875 Eye Street, N.W., Suite 1200, Washington, DC, 20006, US

(73) Assignee: PANASONIC CORPORATION, Osaka (JP)

(21) Appl. No.: 12/671,191

(22) PCT Filed: Jul. 30, 2008
(86) PCT No.: PCT/JP2008/002047

§ 371 Date: Jan. 28, 2010

(30) Foreign Application Priority Data
Jul. 31, 2007 (JP) 2007-199732

(51) Int. Cl. H04W 40/00; H03M 13/05; G06F 11/10

(52) U.S. Cl. 370/328; 714/752; 714/E11.032

(57) ABSTRACT

It is an object to provide a wireless communication device configured to reduce a communication resource necessary for retransmission, so that data transmission efficiency can be improved. In this device, when an NACK signal is input from an error detecting unit (107), i.e., when receiving data have an error, a retransmission judging unit (109) carries out retransmission judgment processing to judge for every block whether or not block retransmission is required on the basis of an average value of an LLR of each decoding bit included in each block in a plurality of blocks comprised of the divisions of decoding bit sequences input from an LDPC decoding unit (106) in accordance with the magnitude of row weights. Further, the retransmission judging unit (109) judges the plurality of the blocks in order of larger magnitude of the row weights, so that, at the timing of such judgment that the retransmission of some block is required, the retransmission judging unit does not carry out the judgment of the block which has not been judged as to whether or not the retransmission is required. A control signal generating unit (110) generates feedback information based on the judged result input from the retransmission judging unit (109).

### TECHNICAL FIELD

The present invention relates to a radio communication apparatus and retransmission decision method.

### BACKGROUND ART

In recent years, multimedia communication such as data communication and video communication has continued to increase in popularity. Therefore, data sizes are expected to increase even more in the future, and growing demands for higher-speed data rates for mobile communication services are also anticipated.

Then, a fourth-generation mobile communication system called “IMT-Advanced” has been studied by the ITU-R (International Telecommunication Union Radio Communication Sector), and an LDPC (Low-Density Parity-Check) code becomes a focus of attention as err or correcting code for implementing a downlink speed of up to Gbps Use of an LDPC code as an error correcting code enables decoding processing to be parallelized, allowing decoding processing to be speeded up compared with the use of a turbo code that requires iterative serial execution of decoding processing.

LDPC encoding is performed using a parity check matrix where a large number of 0s and a small number of 1s are arranged. A radio communication apparatus on the transmitting side encodes a transmission bit sequence using a parity cheek matrix, to obtain an LDPC codeword composed of systematic bits and parity bits. A radio communication apparatus on the receiving side decodes received data by iteratively executing passing the likelihoods of individual bits in the row direction of the parity check matrix and in the column direction of the parity check matrix, to acquire a received bit sequence. Here, the number of 1s included in each column in a parity check matrix is called the column degree, and the number of 1s included in each row in a parity check matrix is called the row degree. A parity check matrix can be represented by a Tanner graph, which is a two-part graph composed of rows and columns. In a Tanner graph, each row in a parity check matrix is called a check node, and each column in a parity check matrix is called a variable node. Variable nodes and check nodes of a Tanner graph are connected in accordance with the arrangement of 1s in the parity check matrix, and a radio communication apparatus on the receiving side decodes received data by iteratively executing passing likelihoods between connected nodes, to obtain a received bit sequence.

HARQ (Hybrid ARQ) combines ARQ (Automatic Repeat reQuest) and error correcting codes. With HARQ, a radio communication apparatus on the receiving side feeds back an ACK signal as a response signal to a radio communication apparatus on the transmitting side if there is no error in received data, and a NACK signal if there is an error in received data. Also, the radio communication apparatus on the receiving side combines data retransmitted from the radio communication apparatus on the transmitting side and data received in the past, and performs error correcting decoding on the combined data. By this means, SINR and coding gain improvements are achieved, and received data can be decoded with fewer retransmissions than in the case of ordinary ARQ.

RB (Reliability-Based)-HARQ is one of HARQ. With RB-based HARQ, a radio communication apparatus on the transmitting side generates retransmission data based on feedback information from a radio communication apparatus on the receiving side.

A conventional technique of RB-HARQ that uses LDPC codes for error correcting codes includes feeding back the row numbers that are likely to contain many errors among the rows in the parity check matrix (see Non-Patent Document 1). A radio communication apparatus on the transmitting side retransmits bits corresponding to “1s” included in the row numbers designated in the feedback information.

Non-Patent Document 1: Y. Inaba, T. Ohtsuki, “Reliability-Based Hybrid ARQ (RB-HARQ) Schemes using Low-Density Parity-Check (LDPC) Codes,” IEICE Technical Report, RCS2004-281, pp. 129-134, 2005-1

### DISCLOSURE OF INVENTION

### Problems to be Solved by the Invention

Here, with LDPC encoding, error rate performance varies according to a column degree of each variable node. Accordingly, when RB-HARQ is performed using an LDPC code for error correcting codes, when a parity check matrix that is likely to contain bits with many errors is retransmitted on a per row basis without taking into consideration on the column degree of each bit, hits that do not require retransmission, that is, bits of good error rate performance may also be retransmitted, and therefore, the efficiency of communication resource use decreases.

It is therefore an object of the present invention to provide a radio communication apparatus and a retransmission decision method that reduce communication resources required for retransmission and improve data transmission efficiency.

### Means for Solving the Problem

The radio communication apparatus of the present invention adopts the configuration including: a receiving section that receives one of a plurality of blocks configured by dividing, according to a size of a column degree in a parity check matrix, bits of a codeword acquired by low density parity check encoding using the parity check matrix; and a decision section that performs decision processing of deciding whether or not the blocks require retransmission on a per block basis, based on a likelihood of each of the plurality of blocks.

### ADVANTAGEOUS EFFECTS OF INVENTION

According to the present invention, it is possible to reduce communication resources required for retransmission and improve data transmission efficiency.

### BRIEF DESCRIPTION OF DRAWINGS

FIG. 1 is a block diagram showing a configuration of the radio communication apparatus on the receiving side according to Embodiment 1 of the present invention;

FIG. 2 is a parity check matrix according to Embodiment 1 of the present invention;

FIG. 3 is a Tanner graph according to Embodiment 1 of the present invention;

FIG. 4 shows a block diagram according to Embodiment 1 of the present invention;

FIG. 5 is a flow chart of the retransmission decision processing according to Embodiment 1 of the present invention;

FIG. 6 shows a relationship between the decision result and the feedback information according to Embodiment 1 of the present invention;

FIG. 7 is a block diagram showing a configuration of the radio communication apparatus on the transmitting side according to Embodiment 1 of the present invention;

FIG. 8 shows the retransmission processing according to Embodiment 1 of the present invention;

FIG. 9 shows a block diagram according to Embodiment 2 of the present invention; and

FIG. 10 shows a block diagram according to Embodiment 3 of the present invention.

### BEST MODE FOR CARRYING OUT THE INVENTION

Now embodiments of the present invention will be described in detail with reference to the accompanying drawings.

### Embodiment 1

With the present embodiment, amongst a plurality of blocks configured in divisions according to the size of column degree in a parity check matrix, retransmission decision processing to decide whether or not blocks require retransmission in order from the block of the largest column degree in the parity check matrix, is performed.

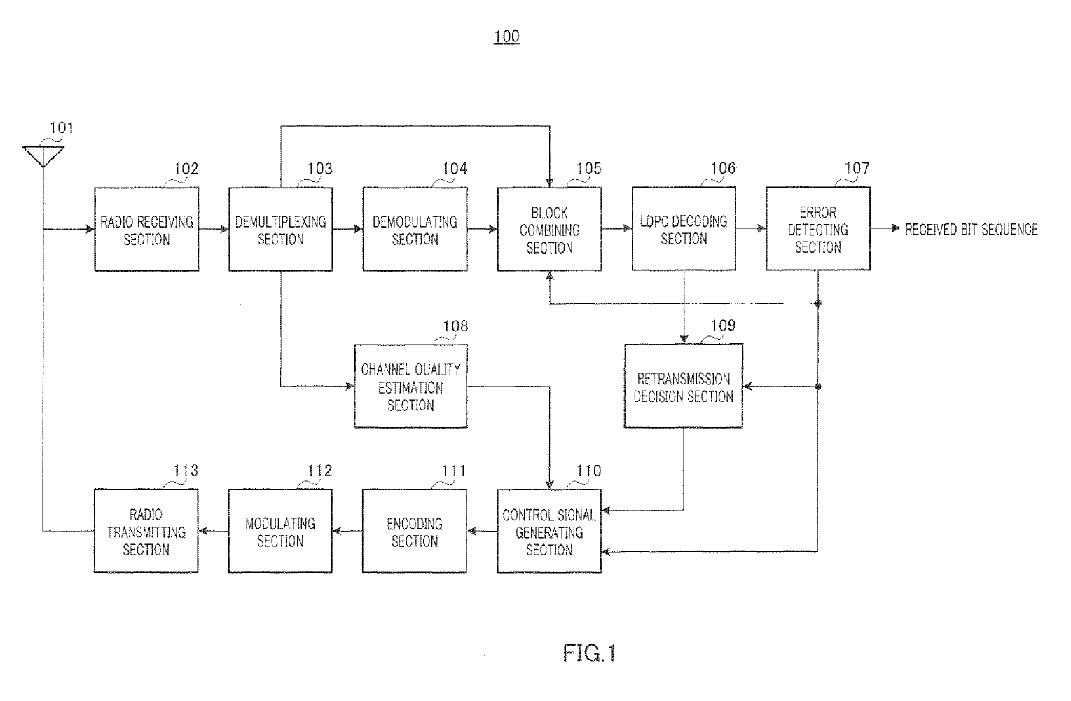

The radio communication apparatus on the receiving side according to the present embodiment will be described. FIG. 1 shows the configuration of radio communication apparatus 100 on the receiving side according to the present embodiment.

In radio communication apparatus 100 on the receiving side, radio receiving section 102 receives a multiplexed signal transmitted from a radio communication apparatus on the transmitting side through antenna 101, performs receiving processing including down-conversion and A/D conversion on the received signal and outputs the resulting signal to demultiplexing section 103. This received signal includes data symbols, pilot signals and control signals designating a coding rate determined in a radio communication apparatus on the transmitting side and retransmission block information designating blocks to be retransmitted.

Demultiplexing section 103 demultiplexes the received signal into the data symbols, the pilot signals and the control signals. Then, demultiplexing section 103 outputs the data symbols to demodulating section 104, the pilot signals to channel quality estimation section 108 and the control signals to block combining section 105.

Demodulating section 104 demodulates the data symbols to acquire received data and outputs the received data to block combining section 105.

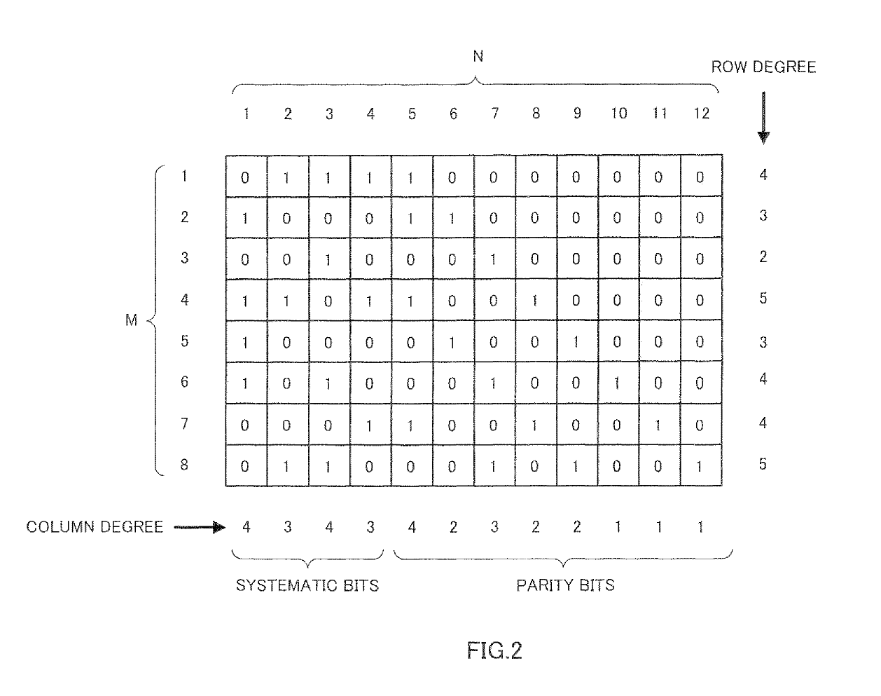

When the first transmission data (initial transmission data) is received, block combining section 105 stores the received data and outputs it to LDPC decoding section 106. Meanwhile, when second or subsequent transmission data (retransmission data) is received, block combining section 105 specifies received bits forming the received data based on the parity check matrix (FIG. 2) and control information received as input from demultiplexing section 103 (i.e. coding rate and retransmission block information), combines that received data and stored data, stores the resulting data, and output the resulting data to LDPC decoding section 106. Further, when an ACK signal is received as input from error detecting section 107, that is, when there is no error in the received data outputted to LDPC decoding section 106, block combining section 105 discards the stored received data.

LDPC decoding section 106 performs LDPC decoding on the data received as input from block combining section 105 using the parity check matrix, to acquire decoded bit sequence. This decoded bit sequence is outputted to error detecting section 107. Further, LDPC decoding section 106 outputs an LLR (Log-Likelihood Ratio) of each decoded bit in the resulting decoded bit sequence to retransmission decision section 109.

Error detecting section 107 performs error detection on the decoded bit sequence received as input from LDPC decoding section 106. As a result of the error detection, when there is an error in the decoded bits, error detecting section 107 generates a MACK signal as a response signal and outputs it to block combining section 105, retransmission decision section 109 and control signal generating section 110, and, when there is not an error in the decoded bits, error detecting section 107 generates an ACK signal as a response signal and outputs it to block combining section 105, retransmission decision section 109 and control signal generating section 110. Further, when there is not an error in the decoded bits, error detecting section 107 outputs the decoded bit sequence as a received bit sequence.

Meanwhile, channel quality estimation section 108 estimates channel quality using the pilot signal received as input from demultiplexing section 103. Here, channel quality estimation section 108 estimates the SINR (Signal to Interference and Noise Ratio) of the pilot signal as channel quality, and outputs the estimated SINR to control signal generating section 110.

When a NACK signal is received as input from error detecting section 107, that is, when there is an error in the received data, amongst a plurality of blocks configured by dividing the decoded bit sequence according to the size of column degree in the parity check matrix, retransmission decision section 109 performs retransmission decision processing to decide whether or not the blocks require retransmission on a per block basis based on average values of the LLRs (hereinafter “average LLRs”) of the decoded bits included in each block. To be more specific, retransmission decision section 109 compares the average LLR of each block and a predetermined threshold value. Then, when the average LLR of a block reaches the threshold value, retransmission decision section 109 decides that it is not necessary to retransmit that block, and, when the average LLR of a block does not reach the threshold value, retransmission decision section 109 decides that it is necessary to retransmit that block. Further, in retransmission decision section 109, decision is made in order from the block of the largest column degree among a plurality of blocks, and, when a given block is decided to require retransmission, decision is not made for the blocks that are not decided whether or not to require retransmission. That is, retransmission decision section 109 cancels retransmission decision processing when a given block is decided to require retransmission. Then, retransmission decision section 109 outputs the decision result designating retransmission blocks to control signal generating section 110. The retransmission decision processing in retransmission decision section 109 will be described later.

Control signal generating section 110 generates a CQI (Channel Quality Indicator) corresponding to the SINR received as input from channel quality estimation section 108 and generates feedback information based on the decision result received as input from retransmission decision section 109. Then, control signal generating section 110 outputs the control signal including the generated CQI, the generated feedback information and the response signal received as input from error detecting section 107, to encoding section 111. The feedback information generating processing in control signal generating section 110 will be described later.

Encoding section 111 encodes the control signal and outputs the encoded control signal to modulating section 112.

Modulating section 112 modulates the control signal and outputs the modulated signal to radio transmitting section 113.

Radio transmitting section 113 performs transmitting processing including D/A conversion, amplification and up-conversion on the control signal, and transmits the signal after transmitting processing to a radio communication apparatus on the transmitting side from antenna 101.

Next, the retransmission decision processing in retransmission decision section 109 will be described.

FIG. 2 shows an 8×12 parity check matrix as an example. As shown here, a parity check matrix is represented by a M×N matrix and is composed of 0s and 1s.

Each column in a parity check matrix corresponds to bits in the LDPC codeword. That is, when LDPC encoding is performed using the parity check matrix shown in FIG. 2, a 12-bit LDPC codeword is acquired.

Further, in the parity cheek matrix shown in FIG. 2, the column degree of the first column is the number of is in the first column, that is, 4, and the column degree of the second column is the number of is in the second column, that is, 3. Therefore, in the 12-bit LDPC codeword, the column degree of the first bit is 4 and the column degree of the second bit is 3. The same will apply to the third to twelfth column.

Likewise, in the parity check matrix shown in FIG. 2, the row degree of the first row is the number of 1s in the first row, that is, 4, and the row degree of the second row is the number of 1s in the second row, that is, 3. The same will apply to the third to eighth row.

Furthermore, the parity check matrix shown in FIG. 2 can be represented by a Tanner graph composed of the rows and columns in the parity check matrix.

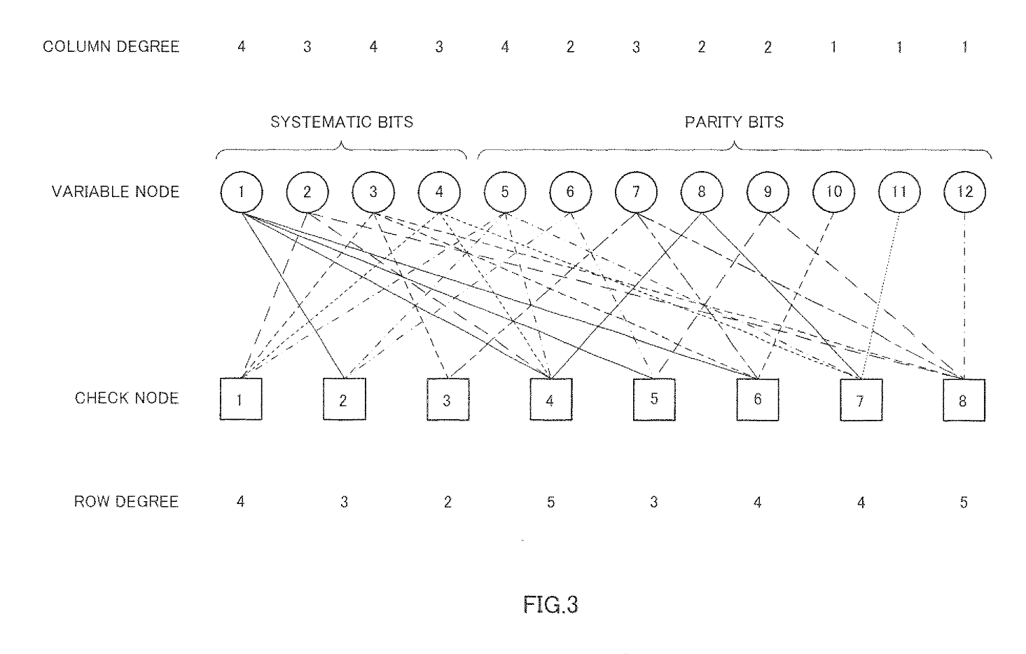

FIG. 3 shows a Tanner graph corresponding to the parity check matrix in FIG. 2. A Tanner graph is composed of check nodes corresponding to rows of a parity check matrix and variable nodes corresponding to columns in a parity check matrix. That is, the Tanner graph corresponding to an 8×12 parity check matrix is a two-part graph composed of eight check nodes and twelve variable nodes.

Furthermore, variable nodes in the Tanner graph correspond to bits in the LDPC codeword.

Here, the variable nodes and check nodes in the Tanner graph are connected in accordance with the arrangement of “1”s in the parity check matrix.

Specific explanation will be given based on the variable nodes. Variable node 1 in the Tanner graph shown in FIG. 3 corresponds to the first column (N=1) in the parity check matrix shown in FIG. 2. The column degree of the first column in the parity check matrix is 4, and the rows in which 1s are located in the first column are the second row, fourth row, fifth row and sixth row. Therefore, there are four connections from variable node 1, that is, check node 2, check node 4, check node 5 and check node 6. Likewise, variable node 2 in the Tanner graph corresponds to the second column (N=2) in the parity check matrix. The column degree in the second column in the parity check matrix is 3, and the rows in which 1s are located in the second column are the first row, fourth row and eighth row. Therefore, there are three connections from variable node 2, that is, check node 1, check node 4 and check node 8. The same will apply to variable node 3 to variable node 12.

Likewise, to give a concrete description based on check nodes, check node 1 of the Tanner graph shown in FIG. 3 corresponds to the first row (M=1) in the parity check matrix shown in FIG. 2. The row degree of the first row in the parity check matrix is 4, and the columns in which 1s are located in the first row are the second column, third column, fourth column and fifth column. Therefore, there are four connections from check node 1, that is, variable node 2, variable node 3, variable node 4 and variable node 5. Likewise, check node 2 in the Tanner graph corresponds to the second row (M=2) in the parity check matrix. The row degree of the second row of the parity check matrix is 3, and the columns in which 1s are located in the second row are the first column, fifth column, and sixth column. Therefore, there are three connections from check node 2, that is, variable node 1, variable node 5 and variable node 6. The same applies to check node 3 to check node 8.

In this way, in a Tanner graph, the variable nodes and check nodes are connected in accordance with the arrangement of 1s in a parity check matrix. That is, the number of check nodes connected to each variable node in a Tanner graph equals the column degree of a column in a parity check matrix. Also, check nodes with which each variable node is connected in a Tanner graph are the check nodes corresponding to the rows in which 1s are located in the columns in a parity check matrix. Likewise, the number of variable nodes connected to each check node in a Tanner graph equals the row degree of a row in a parity check matrix. Also, variable nodes with which each cheek node is connected in a Tanner graph are the variable nodes corresponding to the column in which 1s are located in the rows in a parity check matrix.

The radio communication apparatus 100 on the receiving side passes likelihoods between the variable nodes, through the check nodes, and decodes received data by iteratively updating the likelihoods of the variable nodes. By this means, the number of times to pass likelihoods to other check nodes increases when a variable node has a larger number of connections with check nodes (i.e. variable nodes having a larger column degree), so that the effect of likelihood updating is significant and error rate performance improve.

Further, the LLRs (absolute values) in received data after decoding in radio communication apparatus 100 on the receiving side correspond to the size of column degree. That is, error rate performance better improves when a bit has a larger LLR (that is, when a bit has a larger column degree).

Then, retransmission decision section 109 performs retransmission decision processing based on the average LLR in each block for a plurality of blocks configured by dividing each decoded bit sequence according to the number of connections with check nodes, that is, the size of column degree.

Now, a specific explanation will be given below. In the following explanation, the received data length is 12 bits and the coding rate in the LDPC decoding section (i.e. mother coding rate) is ⅓. Further, the coding rate received as input from demultiplexing section 103 is ⅓. That is, LDPC decoding section 106 performs LDPC decoding on 12-bit received data using the parity check matrix shown in FIG. 2, to acquire a 12-bit decoded bit sequence corresponding to an LDPC codeword composed of four systematic bits and eight parity bits. Further, the block length of each block configured by dividing the decoded bit sequence is 3 bits.

First, retransmission decision section 109 extracts every three bits in three bit units in order from the bit corresponding to the variable node of the largest column degree (the bit corresponding to the variable node of the largest number of connections with check nodes) amongst the 12 bits corresponding to the first column to the twelfth column in the parity check matrix shown in FIG. 2 (variable node 1 to variable node 12 in the Tanner graph shown in FIG. 3), to form one block.

That is, retransmission decision section 109 compares the column degree (the number of connections with check nodes) between the first column to the twelfth column in the parity cheek matrix shown in FIG. 2 (i.e. variable node 1 to variable node 12 in the Tanner graph shown in FIG. 3). That is, retransmission decision section 109 compares between: column degree 4 of the first column (the number of connections, 4, with check nodes from variable node 1); column degree 3 of the second column (the number of connections, 3, with check nodes from variable node 2); column degree 4 of the third column (the number of connections, 4, with check nodes from variable node 3); column degree 3 of the fourth column (the number of connections, 3, with check nodes from variable node 4); column degree 4 of the fifth column (the number of connections, 4, with check nodes from variable node 5); column degree 2 of the sixth column (the number of connections, 2, with check nodes from variable node 6); column degree 3 of the seventh column (the number of connections, 3, with check nodes from variable node 7); column degree 2 of the eighth column (the number of connections, 2, with cheek nodes from variable node 8); column degree 2 of the ninth column (the number of connections, 2, with check nodes from variable node 9); column degree 1 of the tenth column (the number of connections, 1, with check nodes from variable node 10), column degree 1 of the eleventh column (the number of connections, 1, with check nodes from variable node 11); and column degree 1 of the twelfth column (the number of connections, 1, with check nodes from variable node 12).

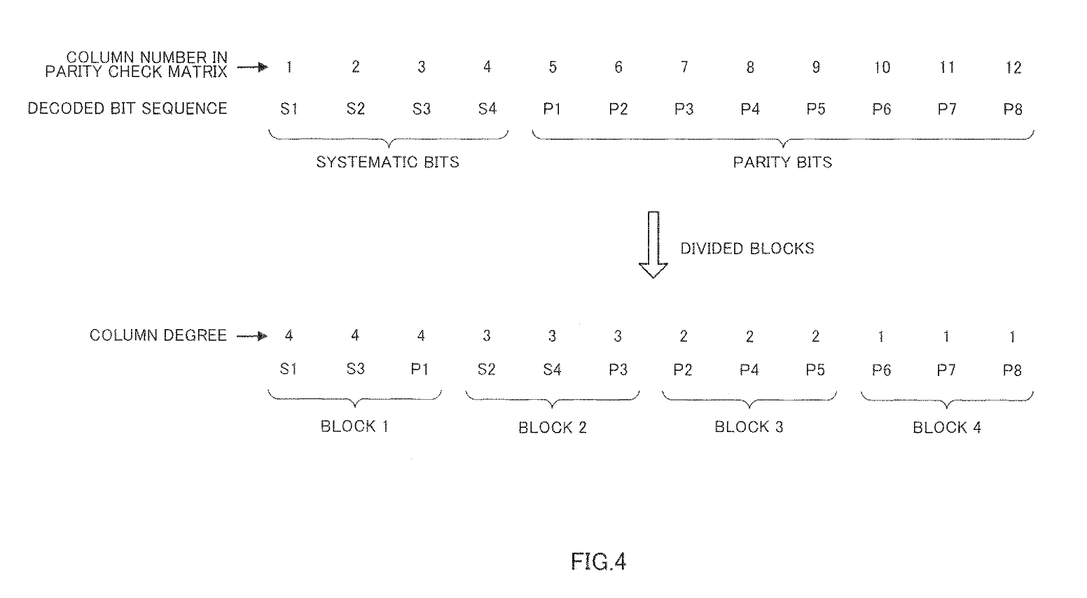

Then, since one block is formed with three bits, as shown in FIG. 4, in the 12-bit decoded bit sequence corresponding to the LDPC codeword composed of four systematic bits S1 to S4 and eight parity bits P1 to P8, retransmission decision section 109 extracts S1 of the first column (variable node 1), S3 of the third column (variable node 3) and P1 of the fifth column (variable node 5), to form block 1, extracts S2 of the second column (variable node 2), S4 of the fourth column (variable node 4) and P3 of the seventh column (variable node 7), to form block 2, extracts P2 of the sixth column (variable node 6), P4 of the eighth column (variable node 8) and P5 of the ninth column (variable node 9), to form block 3, and, extracts P6 of the tenth column (variable node 10), P7 of the eleventh column (variable node 11) and P8 of the twelfth column (variable node 12), to form block 4.

In this way, retransmission decision section 109 form blocks by dividing the decoded bit sequence according to the size of column degree, so that it is possible to include a plurality of bits having similar column degrees in the same block. By this means, the bits forming each block have similar effect of likelihood updating, that is, have similar error rate performance. That is, error rate performance is similar in the same block and, meanwhile, error rate performance clearly varies between blocks. Consequently, retransmission decision section 109 is able to specify only the blocks formed with bits that require retransmission. Further, by grouping bits to create blocks, retransmission decision targets decrease compared with a case where retransmission is decided every bit, so that it is possible to reduce the amount of feedback information.

As described above, the effect of likelihood updating, that is, error rate performance improves better when the bit of larger column degree in a parity check matrix (the bit corresponding to the variable node having a larger number of connections with check nodes in a Tanner graph). That is, when the average LLR of the block formed with the bits having larger column degrees does not reach a threshold value, an average LLR of the block formed with bits having smaller column degrees than that block is likely not to reach the threshold value. For example, unless the average LLR in block 1 shown in FIG. 4 reaches the threshold value, the average LLRs of blocks 2 and 3 having smaller column degrees than block 1 are less likely to reach the threshold value.

Then, retransmission decision section 109 performs retransmission decision processing in order of block 1 formed with the bits of larger column degrees amongst blocks 1 to 4. Further, when a given block is decided to require retransmission, retransmission decision section 109 decides that retransmission is necessary without deciding retransmission of the blocks formed with bits having smaller column degrees than that block, and cancels decision processing. For example, when the average LLR of block 1 does not reach the threshold value, retransmission decision section 109 cancels retransmission decision processing for blocks 2 to 4, and, furthermore, decides that retransmission is required for blocks 2 to 4 in addition to block 1. The same applies to the retransmission decision for block 2 and block 3.

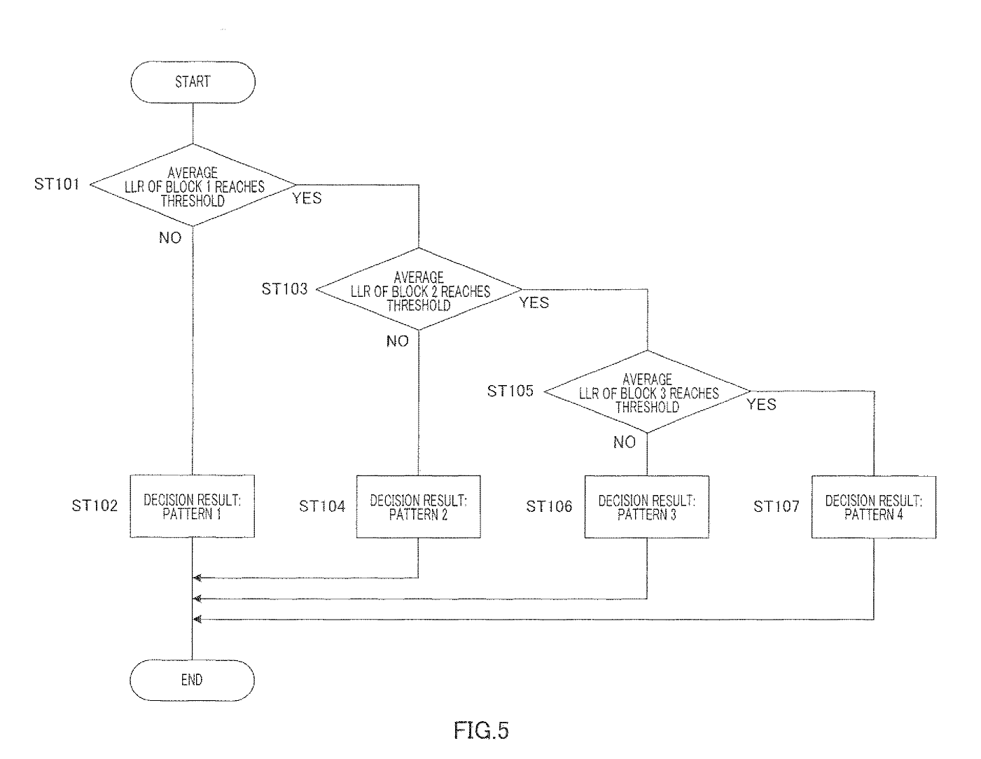

Now, the processing flow of retransmission decision section 109 will be described using the flow chart of FIG. 5.

In ST (step) 101, retransmission decision section 109 calculates the average LLR of S1, S3 and P1 forming block 1 shown in FIG. 4, compares the average LLR of block 1 with the threshold value, and decides whether or not the average LLR of block 1 reaches the threshold value.

If the average LLR of block 1 does not reach the threshold value in ST 101 (ST 101: NO), in ST 102, as blocks that require retransmission, retransmission decision section 109 determines pattern 1 showing blocks 1 to 4 as a decision result.

On the other hand, if the average LLR of block 1 reaches the threshold value in ST 101 (ST 101: YES), in ST 103, retransmission decision section 109 calculates the average LLR of S2, S4 and P3 forming block 2 shown in FIG. 4, and decides whether or not the average LLR of block 2 reaches the threshold value by comparing the average LLR of block 2 and the threshold value.

If the average LLR of block 2 does not reach the threshold value in ST 103 (ST 103: NO), in ST 104, as blocks that require retransmission, retransmission decision section 109 determines pattern 2 showing blocks 2 to 4 as a decision result.

On the other hand, if the average LLR of block 2 reaches the threshold value in ST 103 (ST 103: YES), in ST 105, retransmission decision section 109 calculates the average LLR of P2, P4 and P5 forming block 3 shown in FIG. 4, and decides whether or not the average LLR of block 3 reaches the threshold value by comparing the average LLR of block 3 and the threshold value.

If the average LLR of block 3 does not reach the threshold value in ST 105 (ST 105: NO), in ST 106, as blocks that require retransmission, retransmission decision section 109 determines pattern 3 showing blocks 3 and 4 as a decision result.

On the other hand, if the average LLR of block 3 reaches the threshold value in ST 105 (ST 105: YES), in ST 107, as a block that requires retransmission, retransmission decision section 109 determines pattern 4 showing block 4 as a decision result.

In this way, by deciding retransmission in order from block 1 formed with the bits of larger column degrees, retransmission decision section 109 is able to specify the block of the largest column degree amongst the blocks that require retransmission. Accordingly, it is possible to specify all blocks that require retransmission without deciding retransmission processing of all blocks. Consequently, according to the present embodiment, it is possible to minimize the number of times retransmission processing is decided.

Next, feedback information generating processing in control signal generating section 110 will be described in detail.

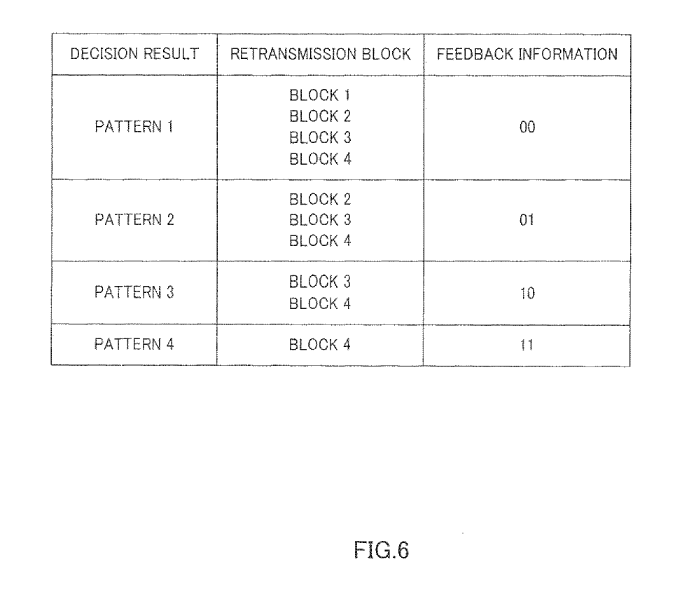

As shown in FIG. 6, control signal generating section 110 generates feedback information based on corresponding relationships between the decision results from retransmission decision section 109 and feedback information. To be more specific, when the decision result from retransmission decision section 109 is pattern 1, that is, when the blocks that require retransmission are blocks 1 to 4, control signal generating section 110 generates feedback information “00.” Similarly, when the decision result from retransmission decision section 109 is pattern 2, that is, when the blocks that require retransmission are blocks 2 to 4, control signal generating section 110 generates feedback information “01.” When the decision result from retransmission decision section 109 is pattern 3, that is, when the blocks that require retransmission are blocks 3 and 4, control signal generating section 110 generates feedback information “10.” When the decision result from retransmission decision section 109 is pattern 4, that is, when the block that requires retransmission is block 4, control signal generating section 110 generates feedback information “11.” The corresponding relationships between decision results (patterns 1 to 4) from retransmission decision section 109 and feedback information (“00,” “01,” “10” and “11”) are not limited to the corresponding relationships shown in FIG. 6. For example, pattern 1 and “11,” pattern 2 and “10,” pattern 3 and “01” and pattern 4 and “00” may be respectively associated.

Here, as shown in FIG. 4, when the number of blocks formed by dividing a decoded bit sequence is four, the patterns of blocks to be retransmitted are fifteen in total, and therefore four bits are required to represent all the patterns. However, like the present embodiment, by performing retransmission decision processing in order from the block of the largest column degree in a parity check matrix, in control signal generating section 110, it is only necessary to have four types of feedback information (patterns 1 to 4) for four blocks, and therefore two bits are enough for feedback information. In this way, according to the present embodiment, it is possible to reduce (halve) the amount of feedback information to feed back to the radio communication apparatus on the transmitting side.

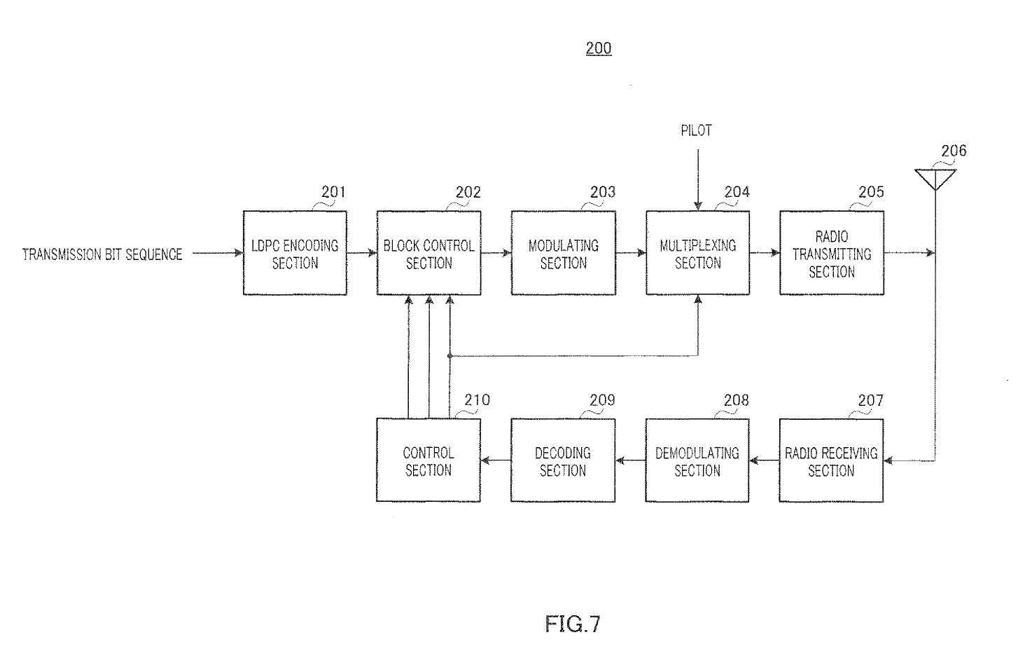

FIG. 7 shows the configuration of radio communication apparatus 200 on the transmitting side according to the present embodiment.

In radio communication apparatus 200 on the transmitting side, LDPC encoding section 201 receives a transmission bit sequence as input. LDPC encoding section 201 performs LDPC encoding on the transmission bit sequence using the same parity check matrix (FIG. 2) as used in LDPC decoding section 106 (FIG. 1), to acquire an LDPC codeword composed of systematic bits and parity bits. This LDPC codeword is outputted to block control section 202. Further, LDPC encoding section 201 outputs the parity check matrix to block control section 202.

Based on the parity check matrix (FIG. 2), as in retransmission decision section 109 (FIG. 1), block control section 202 divides the bits in the LDPC codeword to form a plurality of blocks, and outputs the blocks to modulating section 203. Further, block control section 202 stores the LDPC codeword received as input from LDPC encoding section 201. Then, block control section 202 outputs all bits included in the LDPC codeword upon the first transmission (initial transmission), to modulating section 203. Further, when a NACK signal is received as input from control section 210, that is, upon second or subsequent transmission data (retransmission), block control section 202 outputs selected blocks amongst a plurality of blocks to modulating section 203 based on the coding rate and feedback information from control section 210, and, when an ACK signal is received as input from control section 210, block control section stops outputting blocks to modulating section 203 and discards the stored LDPC codeword.

In the first transmission (initial transmission), modulating section 203 modulates the LDPC codeword received as input from block control section 202, to generate data symbols, and outputs the generated data symbols to multiplexing section 204. Further, in a second or subsequent transmission (retransmission), modulating section 203 modulates the blocks received as input from block control section 202, to generate data symbols, and outputs the generated data symbols to multiplexing section 204.

Multiplexing section 204 multiplexes the data symbols, pilot signals and control signals received as input from control section 210, and outputs the generated multiplexed signal to radio transmitting section 205.

Radio transmitting section 205 performs transmitting processing including D/A conversion, amplification and up-conversion on the multiplexed signal and transmits the multiplexed signal after transmitting processing to radio communication apparatus 100 (FIG. 1) on the receiving side from antenna 206.

Meanwhile, radio receiving section 207 receives the control signal transmitted from radio communication apparatus 100 (FIG. 1) on the receiving side through antenna 206, performs reception processing including down-conversion and A/D conversion on the control signal and, outputs the control signal to demodulating section 208. This control signal includes a CQI generated in the radio communication apparatus on the receiving side, a response signal (an ACK signal or a NACK signal) and feedback information designating the blocks that require retransmission.

Demodulating section 208 demodulates the control signal and outputs the demodulated signal to decoding section 209.

Decoding section 209 decodes the control signal and outputs the CQI, the response signal and the feedback information included in the control signal, to control section 210.

Control section 210 controls the coding rate after controlling the blocks. Then, control section 210 outputs the determined coding rate to block control section 202 and multiplexing section 204. Further, control section 210 outputs the response signal and the feedback information received as input from decoding section 209, to block control section 202.

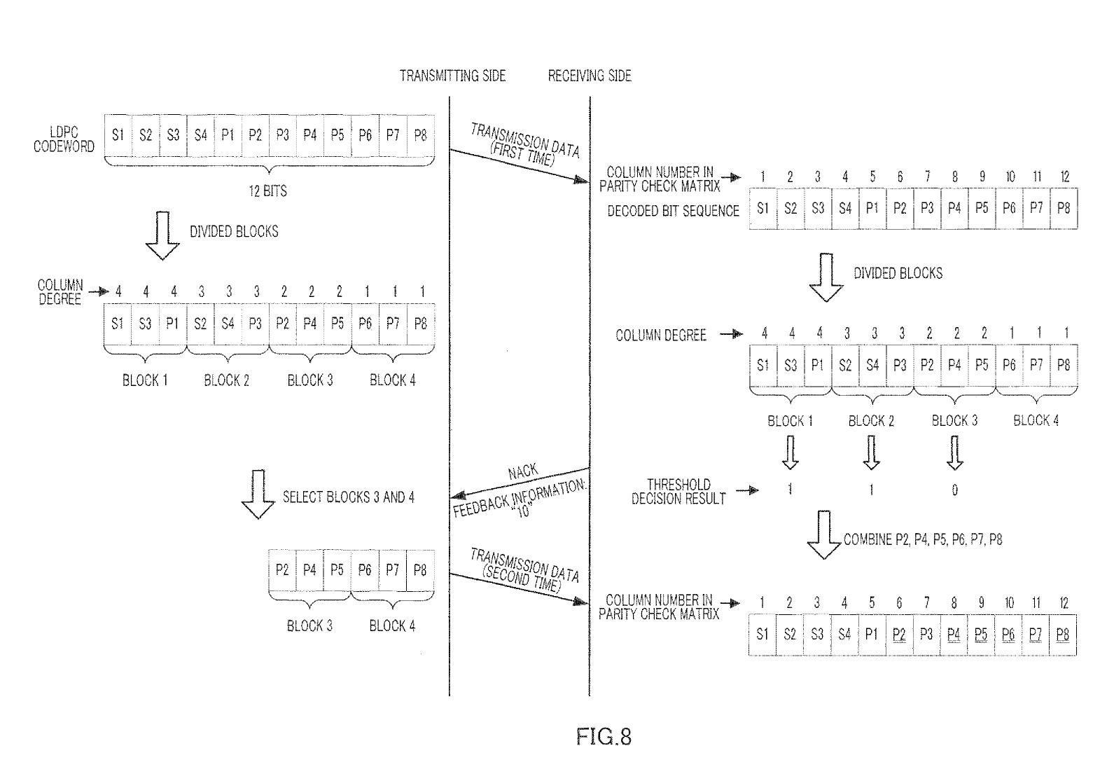

Next, the retransmission processing in the present embodiment will be described using FIG. 8.

Here, a 12-bit LDPC codeword is composed of four systematic bits S1 to S4, eight parity bits P1 to P8. Further, assume that the block length of each block formed by dividing the LDPC codeword is three bits. Further, with retransmission decision section 109 in radio communication apparatus 100 on the receiving side, the threshold decision result when the average LLR of each block reaches the threshold is represented as “1,” and the threshold decision result of when the average LLR of each block does not reach the threshold is represented as “0.”

As shown in FIG. 8, radio communication apparatus 200 (FIG. 7) on the transmitting side transmits a 12-bit LDPC codeword upon the first transmission (initial transmission). Accordingly, radio communication apparatus 100 on the receiving side receives 12-bit received data upon receiving the first transmission data (initial transmission data). Here, assume that error detecting section 107 in radio communication apparatus 100 on the receiving side performs error detection for the decoded bit sequence acquired by performing LDPC decoding for the received data and outputs a NACK signal.

Here, block control section 202 in radio communication apparatus 200 on the transmitting side divides the 12-bit LDPC codeword every three bits in three bit units according to the size of column degrees of the parity check matrix (FIG. 2), to form blocks 1 to 4 shown in FIG. 4. Likewise, retransmission decision section 109 in radio communication apparatus 100 on the receiving side divides the 12-bit decoded bit sequence every three bits in three bit units, to form blocks 1 to 4 shown in FIG. 4.

Then, retransmission decision section 109 in radio communication apparatus 100 on the receiving side calculates the average LLRs of blocks 1 to 4 and compares each calculated average LLR and the threshold value according to the processing flow shown in FIG. 5. Here, as shown in FIG. 8, in retransmission decision section 109, the threshold decision results of blocks 1 and 2 is “1,” and the threshold decision result of block 3 is “0.” That is, retransmission decision section 109 outputs pattern 3 as the decision result to control signal generating section 110 (ST 106 shown in FIG. 5). Then, control signal generating section 110 generates feedback information “10” based on the correspondence relationships between decision results and feedback information (FIG. 6).

Accordingly, as shown in FIG. 8, radio communication apparatus 100 on the receiving side feeds back the control signal including a NACK signal and feedback information “10” to radio communication apparatus 200 on the transmitting side.

Next, block control section 202 in radio communication apparatus 200 on the transmitting side receives feedback information designating a NACK signal and the blocks that require retransmission (blocks 3 and 4) as input from control section 210. Then, as shown in FIG. 8, block control section 202 selects block 3 formed with P2, P4 and P5 and block 4 formed with P6, P7 and P8 amongst blocks 1 to 4, and outputs selected blocks 3 and 4 to modulating section 203.

That is, upon second transmission (first retransmission), radio communication apparatus 200 on the transmitting side transmits blocks 3 and 4 as second transmission data (first retransmission data) to radio communication apparatus 100 on the receiving side.

Then, upon receiving second transmission data (first retransmission data), block combining section 105 in radio communication apparatus 100 on the receiving side combines P2, P4, P5, P6, P7 and P8 included in blocks 3 and 4, and P2, P4, P5, P6, P7 and P8 included in the LDPC codeword stored upon receiving the first transmission data (initial transmission data), respectively.

By this means, upon receiving the first transmission data (initial transmission data), radio communication apparatus 100 on the receiving side feeds back the feedback information to radio communication apparatus 200 on the transmitting side such that radio communication apparatus 200 on the transmitting side retransmits only the blocks having average LLRs less than the threshold value (blocks 3 and 4 in FIG. 8), that is, only the blocks including a plurality of bits that are likely to contain errors. By this means, upon receiving second transmission data (first retransmission data), radio communication apparatus 100 on the receiving side is able to receive only the blocks including a plurality of bits that are likely to have errors (blocks 3 and 4 in FIG. 8), it is possible to minimize the use of communication resource for retransmission.

In this way, according to the present embodiment, whether or not retransmission is necessary is decided every block formed by dividing a decoded bit sequence according to the size of column degree in a parity check matrix, By this means, the radio communication apparatus on the receiving side is able to decide whether or not to retransmit every block having various column degrees, and, the radio communication apparatus on the transmitting side is able to retransmit only the blocks formed with bits that require retransmission amongst bits in an LDPC codeword. Therefore, according to the present embodiment, it is possible to reduce communication resources required for retransmission and improve data transmission efficiency.

Further, according to the present embodiment, whether or not retransmission is necessary is decided in order from the block of larger column degrees in the parity check matrix. Then, when a given block is decided to require retransmission, the blocks of smaller column degrees in the parity check matrix than that block are determined to be blocks that require retransmission without deciding whether or not retransmission is necessary. By this means, the number of times of retransmission decision processing is smaller than the number of all blocks at the maximum, so that it is possible to reduce the amount of feedback information, Further, all blocks are not necessarily subject to retransmission decision, so that it is possible to reduce the retransmission decision processing.

### Embodiment 2

With the present embodiment, a case will be explained where a block with the smaller block length is formed with bits having larger column degrees.

The operations of retransmission decision section 109 according to the present embodiment will be explained below.

Amongst the bits in a decoded bit sequence, when there are bits which correspond to smaller column degrees in the parity check matrix and which apparently contain errors, the bit to mask the boundary whether or not retransmission becomes necessary is more likely to be a bit of a large column degree in the parity check matrix (bit corresponding to the variable node having the large number of connections with check nodes in a Tanner graph). That is, when a plurality of blocks are formed by dividing bits in an LDPC codeword, it is preferable that the block length of the blocks formed with the bits having larger column degrees is made shorter, and boundaries masked by bits to decide whether or not retransmission is necessary are provided more minutely.

Then, retransmission decision section 109 according to the present embodiment, retransmission decision processing is performed for a plurality of blocks formed with bits of larger column degrees when the block length is shorter.

Now, a specific explanation will be given below. In the following explanation, similar to Embodiment 1 (FIG. 4), the received data length is 12 bits, the mother coding rate is ⅓, and the coding rate determined in control section 110 in the radio communication apparatus (FIG. 7) on the transmitting side is ⅓. Further, the bits having small column degrees with apparent errors are bits having column degree 1 or column degree 2, and the bits having large column degrees are bits having column degree 3 and column degree 4. Further, assume that the block length of each block configured by dividing the decoded bit sequence is 2 bits for a block of a large column degree and 6 bits for a block of a small column degree.

Similar to Embodiment 1, retransmission decision section 109 extracts the bit in order from the bit corresponding to the variable node of the largest column degree (the bit corresponding to the variable node having the largest number of connections with check nodes) amongst the 12 bits corresponding to the first column to the twelfth column in the parity check matrix shown in FIG. 2 (variable node 1 to variable node 12 in the Tanner graph shown in FIG. 3), to form one block.

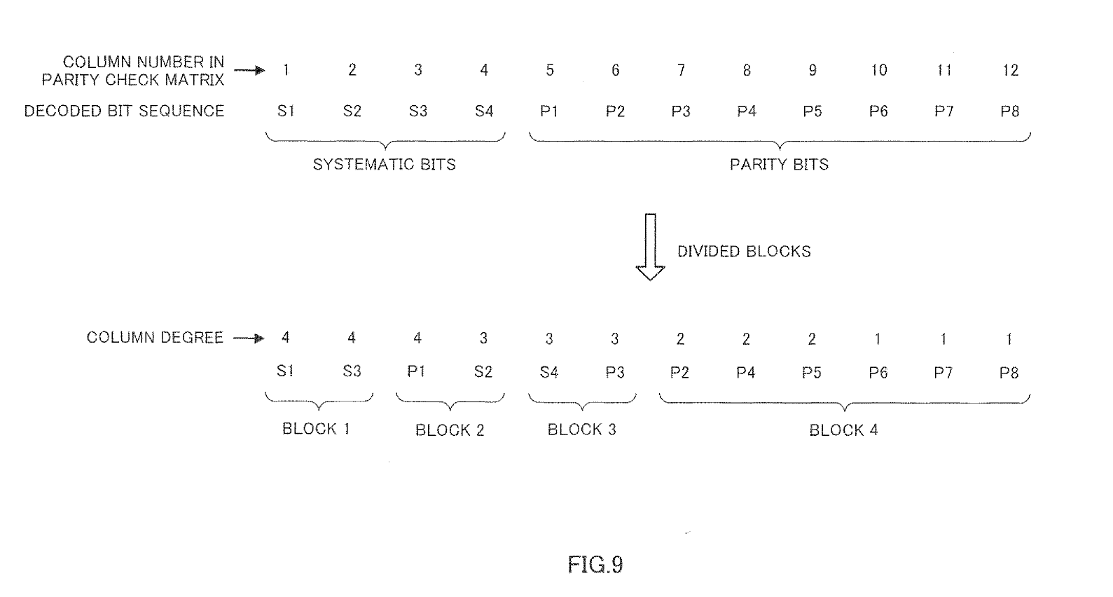

As for the bits having large column degrees, that is, as for the bits having column degree 3 or 4, one block is formed with two bits and therefore, as shown in FIG. 9, in the 12-bit decoded bit sequence corresponding to the LDPC codeword composed of four systematic bits S1 to S4 and eight parity bits P1 to P8, retransmission decision section 109 extracts S1 of the first column of column degree 4 (variable node 1 having the number of connections with check nodes, 4), and S3 of the third column of column degree 4 (variable node 3 having the number of connections with check nodes, 4) to form block 1, extracts P1 of the fifth column of column degree 4 (variable node 5 having the number of connections with check nodes, 4) and S2 of the second column of column degree 3 (variable node 2 having the number of connections with check nodes, 3), to form block 2, and extracts S4 of the fourth column of column degree 3 (variable node 4 having the number of connections with check nodes, 3), and P3 of the seventh column of column degree 3 (variable node 7 having the number of connections with check nodes, 3), to form block 3.

Also, as for the bits having small column degrees, that is, as for the bits having column degree 1 or 2, one block is formed with 6 bits, and therefore, as shown in FIG. 9, retransmission decision section 109 extracts P2 of the sixth column of column degree 2 (variable node 6 having the number of connections with check nodes, 2), P4 of the eighth column of column degree 2 (variable node 8 having the number of connections with check nodes, 2), P5 of the ninth column of column degree 2 (variable node 9 having the number of connections with check nodes, 2), P6 of the tenth column of column degree 1 (variable node 10 having the number of connections with check nodes, 1), P7 of the eleventh column of column degree 1 (variable node 11 having the number of connections with check nodes, 1), and P8 of the twelfth column of column degree 1 (variable node 12 having the number of connections with check nodes, 1), to form block 4.

In this way, the 6 bits of P2, P4, P5, P6, P7 and P8 having the column degree 1 or 2, that is, the 6 bits with apparent errors form one block, and, meanwhile, the 6 bits of S1, S3, P1, S2, S4 and P3 having the column degree 4 or 3, that is, the 6 bits that are less likely to have errors are divided into every two bits in two bit units, to form three blocks. By this means, it is possible to provide more borders for bits that are less likely to have errors and perform retransmission decision processing.

Further, block control section 202 in radio communication apparatus 200 (FIG. 7) on the transmitting side determines the configuration of the blocks in the same manner as in retransmission decision section 109, and selects the retransmission target blocks according to the feedback information fed back from radio communication apparatus 100 on the receiving side.

In this way, according to the present embodiment, by dividing bits having larger column degrees, blocks with shorter block lengths than the blocks as in Embodiment 1 are formed. This makes it possible to decide with better accuracy the border between blocks that require retransmission and blocks that do not require retransmission. Consequently, according to the present embodiment, compared with Embodiment 1, it is possible to reduce more bits that do not require retransmission and yet are retransmitted.

Although a case has been explained with the present embodiment where one block is formed by the bits of small column degrees with apparent errors, with the present invention, the bits of small column degrees may be divided according to the size of column degree, to form a plurality of blocks.

### Embodiment 3

A case will be explained with the present embodiment where, by subdividing blocks that are decided not to require retransmission, a plurality of blocks are formed.

The operations of retransmission decision section 109 according to the present embodiment will be explained.

Radio communication apparatus 100 on the receiving side decides retransmission of the blocks based on the average LLR of each block. Accordingly, although the LLRs of decoded bits forming part of a block are low, if the LLRs of decoded bits other than those bits are high, the average LLR is more likely to reach a threshold. That is, when the LLRs of decoded bits vary in a block, although there are bits that require retransmission, the average LLR of the block reaches the threshold, and therefore it may be decided that retransmission is not required. Here, the possible reasons that the LLRs of decoded bits vary in a block include, for example, the difference between the size of row degree of the decoded bits. With LDPC encoding, the effect of likelihood updating, that is, error rate performance varies according to the size of row degree (the number of connections with variable nodes from the check node connected with the variable nodes corresponding to the decoded bits), and, in addition, the size of column degree (the number of connections with check nodes from the variable node corresponding to the decoded bit).

Then, when either of a plurality of blocks is received after retransmission decision for each block is finished, retransmission decision section 109 performs retransmission decision processing of a plurality of blocks formed by subdividing the blocks that have been decided not to require retransmission.

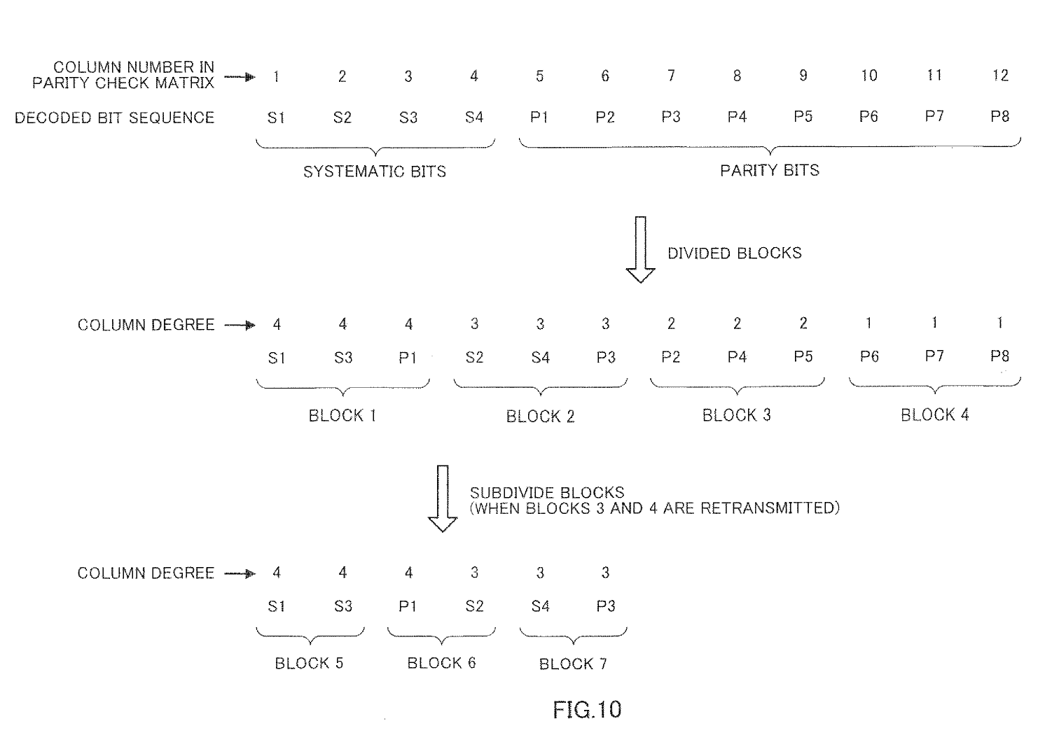

Now, a specific explanation will be given below. In the following explanation, similar to Embodiment 1 (FIG. 4), the received data length is 12 bits, the mother coding rate is ⅓, and the coding rate determined in control section 210 in the radio communication apparatus 200 (FIG. 7) on the transmitting side is ⅓. Further, the block length of each block configured by dividing the decoded hit sequence is 3 bits upon the first division, and 2 bits upon a second division (subdivision). Accordingly, upon receiving the first transmission data (the initial transmission data), similar to Embodiment 1, retransmission decision section 109 extracts every three bits in three bit units in order from the bit of the largest column degree amongst the 12 bits corresponding to the first column to the twelfth column in the parity check matrix shown in FIG. 2 (variable node 1 to variable node 12 in the Tanner graph shown in FIG. 3), to form blocks 1 to 4 shown in the middle of FIG. 10. Further, here, a case where blocks 3 and 4 are retransmitted will be explained.

When blocks 3 and 4, which are second transmission data (first retransmission data), are received from radio communication apparatus 200 (FIG. 7) on the transmitting side, retransmission decision section 109 forms the blocks that have been decided not to require retransmission of when the first transmission data (initial transmission data) is received, that is, the blocks of the shorter block lengths by subdividing blocks 1 and 2. To be more specific, since one block is formed with two bits in the second division (subdivision), as shown in FIG. 10, amongst S1, S3, P1, S2, S4 and P3 forming blocks 1 and 2, retransmission decision section 109 extracts S1 of the first column (variable node 1) and S3 of the third column (variable node 3), to form block 5, extracts P1 of the fifth column (variable node 5) and S2 of the second column (variable node 2), to form block 6, and extracts S4 of the fourth column (variable node 4) and P3 of the seventh column (variable node 7), to form block 7.

By this means, when second transmission data (first retransmission data) is received, as shown in FIG. 10, retransmission decision section 109 performs retransmission decision processing of blocks 5, 6 and 7 formed by dividing the decoded bit sequence. At this time, similar to Embodiment 1, retransmission decision section 109 compares the average LLR and the threshold value in order from the block of the largest column degree. To be more specific, retransmission decision section 109 compares the average LLR of each block and the threshold value in order from block 5, block 6 and block 7.

In this way, retransmission decision section 109 subdivides S1, 53, P1, S2, S4 and P3 included in two blocks of blocks 1 and 2 that have not been retransmitted, to form three smaller blocks of blocks 5 to 7. Accordingly, when receiving second transmission data (first retransmission data) is received, it is possible to provide boundaries for the hits more minutely and perform retransmission decision processing.

Further, block control section 202 in radio communication apparatus 200 (FIG. 7) on the transmitting side determines the configuration of the blocks in the same manner as in retransmission decision section 109, and selects the retransmission target blocks according to the feedback information fed back from radio communication apparatus 100 on the receiving side.

In this way, according to the present embodiment, it is possible to decide retransmission using blocks formed by subdividing a plurality of bits that have not been retransmitted as the number of retransmissions increases. In this way, by subdividing blocks upon receiving retransmission data, even when there are bits that have been decided not to require retransmission in spite of errors, it is possible to decide again accurately whether or not retransmission is required.

A possible reasons that the LLRs of the decoded bits vary in a block include depending on the influence of variation of a received channel.

The embodiments of the present invention have been explained.

Further, although cases have been explained with the embodiments where the present invention is implemented in a FDD (Frequency Division Duplex) system, the present invention may be implemented in a TDD (Time Division Duplex) system. In the case of TDD system, the correlation between uplink channel characteristics and downlink channel characteristics is very high, so that radio communication apparatus 200 on the transmitting side can estimate received quality in radio communication apparatus 100 on the receiving side using signals from radio communication apparatus 100 on the receiving side. Therefore, in the case of TDD system, radio communication apparatus 100 on the receiving side may not report channel quality by CQI and radio communication apparatus 200 on the transmitting side may estimate channel quality.

Further, the parity check matrix shown in FIG. 2 is an example, and a parity check matrix utilized to implement the present invention is not limited to the parity check matrix shown in FIG. 2.

Further, as shown in FIG. 8, although cases have been explained with the above embodiments about the operation up to receiving second transmission data (first transmission data) in radio communication apparatus 100 on the receiving side, when data is further retransmitted, the operation may return to the threshold decision again and retransmission may be carried out.

A variable node may be referred to as a “bit node.”

Further, although cases have been explained with radio communication apparatus 100 (FIG. 1) on the receiving side and radio communication apparatus 200 (FIG. 7) on the transmitting side of the above embodiments where a plurality of blocks are formed based on a predetermined block length, with the present invention, the block length may be determined on a per retransmission basis based on a mother coding rate, a coding rate after the block control or the amount of retransmission data.

Further, retransmission decision section 109 in the above embodiments may use a common threshold value for each block, and use different threshold values between blocks. For example, retransmission decision section 109 sets up respective threshold values for blocks according to the column degrees of the blocks in advance. That is, retransmission decision section 109 sets up an adequate threshold value according to an extent of errors in each block.

Further, the LLR (absolute value) for a decoded bit increases when the number of retransmission increases, so that retransmission decision section 109 may set up a threshold again according to the number of retransmission.

Further, error detection section 107 may perform error detection by CRC (Cyclic Redundancy Cheek).

Further, although cases have been explained with the above embodiments where the coding rate after block control set up in control section 210 in the radio communication apparatus 200 (FIG. 7) on the transmitting side is the same as the mother coding rate, the coding rate after block control is not limited to the same as the mother coding rate. For example, when bits in an LDPC codeword are divided and the divided bits are transmitted sequentially, the coding rate after the block control is greater than the mother coding rate as the number of transmissions decreases. Also, for example, when part of bits in an LDPC codeword is repeated, a coding rate after the block control is smaller than the mother coding rate. At this time, control section 210 may determine the coding rate after block control according to a CQI received as input. Further, the radio communication apparatus on the receiving side may calculate the number of padding bits or the number of repetition bits according to the difference between the mother coding rate and the coding rate after block control.

Further, the coding rate set in control section 210 of radio communication apparatus 200 on the transmitting side is not limited to coding rates to be determined according to channel quality, and, may be a fixed rate.

Further, although, with the present embodiments, SINR is estimated as channel quality, the SNR, SIR, CINR, received power, interference power, hit error rate, throughput, MCS (Modulation and Coding Scheme) that achieves a predetermined error rate, and so on may be estimated as channel quality. Further, a CQI may be referred to as “CSI (Channel State Information).”

Further, in mobile communication systems, radio communication apparatus 100 on the receiving side may be provided in a radio communication mobile station apparatus and radio communication apparatus 200 on the transmitting side may be provided in a radio communication base station apparatus. Further, radio communication apparatus 100 on the receiving side may be provided in a radio communication base station apparatus and radio communication apparatus 200 on the transmitting side may be provided in a radio communication mobile station apparatus. By this means, it is possible to realize a radio communication base station apparatus and radio communication mobile station apparatus providing an advantage as described above.

Further, a radio communication mobile station apparatus may be referred to as a “UE,” and a radio communication base station apparatus may be referred to as a “Node B.”

Further, although cases have been described with the above embodiment as examples where the present invention is configured by hardware, the present invention can also be realized by software.

Each function block employed in the description of each of the aforementioned embodiments may typically be implemented as an LSI constituted by an integrated circuit.

These may be individual chips or partially or totally contained on a single chip. “LSI” is adopted here but this may also be referred to as “IC,” “system LSI,” “super LSI,” or “ultra. LSI” depending on differing extents of integration.

Further, the method of circuit integration is not limited to LSIs, and implementation using dedicated circuitry or general purpose processors is also possible. After LSI manufacture, utilization of a programmable FPGA (Field Programmable Gate Array) or a reconfigurable process or where connections and settings of circuit cells within an LSI can be reconfigured is also possible.

Further, if integrated circuit technology comes out to replace LSI's as a result of the advancement of semiconductor technology or a derivative other technology, it is naturally also possible to carry out function block integration using this technology. Application of biotechnology is also possible.

The disclosure of Japanese Patent Application No. 2007-199732, filed on Jul. 31, 2007, including the specification, drawings and abstract, is incorporated herein by reference in its entirety.

### INDUSTRIAL APPLICABILITY

The present invention is applicable to, for example, mobile communication systems.

1. A radio communication apparatus on a receiving side, comprising:
a receiving section that receives one of a plurality of blocks configured by dividing, according to a size of a column degree in a parity check matrix, bits of a codeword acquired by low density parity check encoding using the parity check matrix; and
a decision section that performs decision processing of deciding whether or not the blocks require retransmission on a per block basis, based on a likelihood of each of the plurality of blocks.

2. The radio communication apparatus according to claim 1, wherein the decision section performs the decision processing in order from a block of a largest column degree amongst the plurality of blocks.

3. The radio communication apparatus according to claim 1, wherein the decision section cancels the decision processing when a given block is decided to require the retransmission.

4. The radio communication apparatus according to claim 1, wherein the decision section performs the decision processing for the plurality of blocks, blocks being formed with bits of larger column degrees when lengths of the blocks are shorter.

5. The radio communication apparatus according to claim 1, wherein, amongst the plurality of blocks, the decision section performs the decision processing for a plurality of blocks formed by subdividing blocks that have been decided not to require retransmission.

6. A radio communication apparatus on a transmitting side comprising:
an encoding section that performs low density parity check encoding for a transmission bit sequence using a parity check matrix, to acquire a codeword;
a forming section that divides bits of the codeword according to a size of a column degree in the parity check matrix, to form a plurality of blocks; and
a control section that performs control such that one of the plurality of blocks is transmitted based on control information fed back from a radio communication apparatus on a receiving side.

7. The radio communication apparatus according to claim 1, wherein the radio communication apparatus comprises one of a radio communication base station apparatus and a radio communication mobile station apparatus.

8. The radio communication apparatus according to claim 6, wherein the radio communication apparatus comprises one of a radio communication base station apparatus and a radio communication mobile station apparatus.

9. A retransmission decision method of a plurality of blocks configured by dividing, according to a size of a column degree in a parity check matrix, bits of a codeword acquired by low density parity check encoding using the parity check matrix,
wherein, based on a likelihood of each of the plurality of blocks, whether or not the blocks require retransmission is decided on a per block basis.
